(19) United States
(12) Patent Application Publication
(10) Pub. No.: US 2002/0068470 A1
(43) Pub. Date: Jun. 6, 2002

(54) Holder for compact fluorescent lamps

(76) Inventor: Karl Spiegel, Dornbirn (AT)

Correspondence Address: FITZPATRICK CELLA HARPER & SCINTO, 30 ROCKEFELLER PLAZA, NEW YORK, NY, 10112, US

(21) Appl. No.: 09/996,690

(22) Filed: Nov. 30, 2001

(30) Foreign Application Priority Data
Dec. 4, 2000 (DE) 200 20 546.3

(51) Int. Cl. H05K 1/00; H01R 12/00

(52) U.S. Cl. 439/76.1

(57) ABSTRACT

The invention relates to a holder (21) for compact fluorescent lamps (10a, 10b) which, in dependence upon whether they are operated with a magnetic or an electronic ballast, have either two contact pins (K1) and a longer plug base (12b) or four contact pins (K1) and a shorter plug base (12a), the holder (21) having a plug recess (22) the depth (T1) of each is at least equal to the length (L2) of the longer plug base (12b), the holder further having four contact sleeves (K2) for receiving the two or the four contact pins (K1), and if desired a stop element (22) effective in the base recess (22) being provided, which in the case of need limits the insertion depth of the plug recess (21) to that of the shorter plug base (12a). In order to reduce manufacturing and installation outlay, when a stop element (23) is needed, this is formed in one piece with the holder (21).

### BACKGROUND OF THE INVENTION

1. Field of the Invention

The invention relates to a holder for compact fluorescent lamps which, in dependence upon whether they are operated with a magnetic or electric balast, have either two contact pins and a longer plug base or four contact pins and a shorter plug base; and more specifically, the invention relates to a holder having a plug recess the depth of which is at least equal to the length of the longer plug base.

“Compact fluorescent lamps” consist of curved fluorescent tubes, both ends of which open into a common plug base. Such compact fluorescent lamps can be operated either with a magnetic or an electronic ballast. In the case of compact fluorescent lamps to be operated with a magnetic ballast, the base has two contact pins; further, a conventional starter is integrated into the base. In the case of compact fluorescent lamps to be operated with an electronic ballast, the base has four contact pins. The two-pin bases and the four-pin bases differ, apart from the number of pins, only in their lengths. The two-pin base is somewhat longer than the four-pin base.

The subject of the present invention are holders for compact fluorescent lamps which are to be operated with electronic ballasts, which—as explained—have four-pin bases. These holders have four contact sleeves for receiving the four contact pins.

Along with this, holders are developed which have only two contact sleeves and are therefore usable only for two-pin base lamps.

The four-pin base holders considered here are normally wired for electronic ballasts. This means that only four-pin base lamps are allowed to be placed in the holders. In order to prevent the placing of two-pin base lamps in four-pin base holders it would normally be sufficient to adapt to the depth of the recess for the base to the length of the (shorter) four-pin bases. In order, however, to have the option to be able to equip four-pin base holders, if appropriate, also with two-pin base lamps and provide them with magnetic ballasts, the depth of the base recess of the holder here considered is adapted to the (greater) length of the two-pin bases.

With four-pin base holders wired for electronic ballasts, at the present time the sole known measure for preventing the undesired placement of a two-pin base lamp is that an annular stop element is placed into the floor of the base recess, the height of which element is equal to the difference between the length of a two-pin base and a four-pin base. The emplacement of such an annular stop element requires, however, an additional cost intensive working step, which must be carried out either by the holder manufacture or by the light manufacture. By means of this additional annular stop element, due to the greater base length, a two-pin base lamp can no longer be placed in a four-pin base holder.

### SUMMARY OF THE INVENTION

The object of the invention is, with the holder of the kind indicated in the introduction, to reduce the outlay for manufacture and installation.

This object is achieved by means of a stop element in the base recess to limit the insertion depth of the plug recess to that of the shorter plug base. Advantageous developments are described and claimed herein

With the holder in accordance with the invention—when a stop element is needed—this is formed in one piece with the holder. By these means, the stop element can be produced in the course of the production of the holder body, so that it needs neither separate production nor a special mounting and also does not need a special installation of the stop element in the base recess. After the production of the holder there are needed with regard to the stop element no further measures, since in this respect the holder is ready for use.

The configuration in accordance with the invention is suitable in particular for such materials of the holder body which can be produced by molding in a mold, in particular by means of injection molding. A suitable material is for example plastics.

It is of significance that the stop element projects into the path of movement which the plug base takes upon being plugged into the plug recess. This can be achieved in that the stop element stands up from the inner wall of the plug recess, which can be realized by means of forming in one piece with the holder body. Preferably the stop element stands up from the floor of the base recess, e.g. in the form of a pin or in the form of a web which may extend over a part of the cross-sectional dimension or over the entire cross-sectional dimension of the holder body. In the latter case the web additionally fulfils the function of a strut stabilizing the plug body.

It is further of advantage to produce the stop element of a material which is so hard or brittle that the stop element can be broken off, e.g. with the aid of a tool, e.g. a screw driver, which is inserted to the base recess and pressed against the stop element with a lever effect.

In order to facilitate the breaking off, a preset break point may be provided on the stop element, which makes it possible on the one hand to break off the stop element with slight exercise of force and further to break it off at a particular point and thus controlled in terms of position.

### BRIEF DESCRIPTION OF THE DRAWINGS

Below, the invention and further advantages which can be achieved thereby will be described in more detail with reference to preferred configurations of an exemplary embodiment.

FIG. 1a is a side view of a compact fluorescent lamp which is set up for operation with an electronic ballast.

FIG. 1b is a view from below of the compact fluorescent lamp of FIG. 1a.

FIG. 2a is side view of a compact fluorescent lamp which is set up for operation with a magnetic ballast.

FIG. 2b is a view from below the compact fluorescent lamp of FIG. 2a.

FIG. 3a is a side view of a compact fluorescent lamp, which may be the first lamp type, set up for operation with an electronic ballast, or which may be the second type, set up for operation with a magnetic ballast.

FIG. 3b is a elevation view taken along a section extending through the axis of a holder for compact fluorescent lamps of FIGS. 1a, 1b, 2a, 2b and 3a.

FIG. 4 is an enlarged elevational view similar to FIG. 3b but showing additional features.

### DETAILED DESCRIPTION OF THE PREFERRED EMBODIMENT

The main components of a compact fluorescent lamp 10a of the first lamp type and 10b of the second lamp type are in each case a base body 11, from which there extends in the one direction a U-shaped fluorescent tube 11a and in the opposite direction a plug base 12a or 12b. Each of the two plug bases consists in each case of a first short and wide plug base section 12c and a longer plug base section 12d or 12e adjoining thereon and tapered with respect to first plug base section. On the plug base sections 12d, 12e there is on both sides in each case a latch projection 13a, which is part of a latch device 13 to be described below.

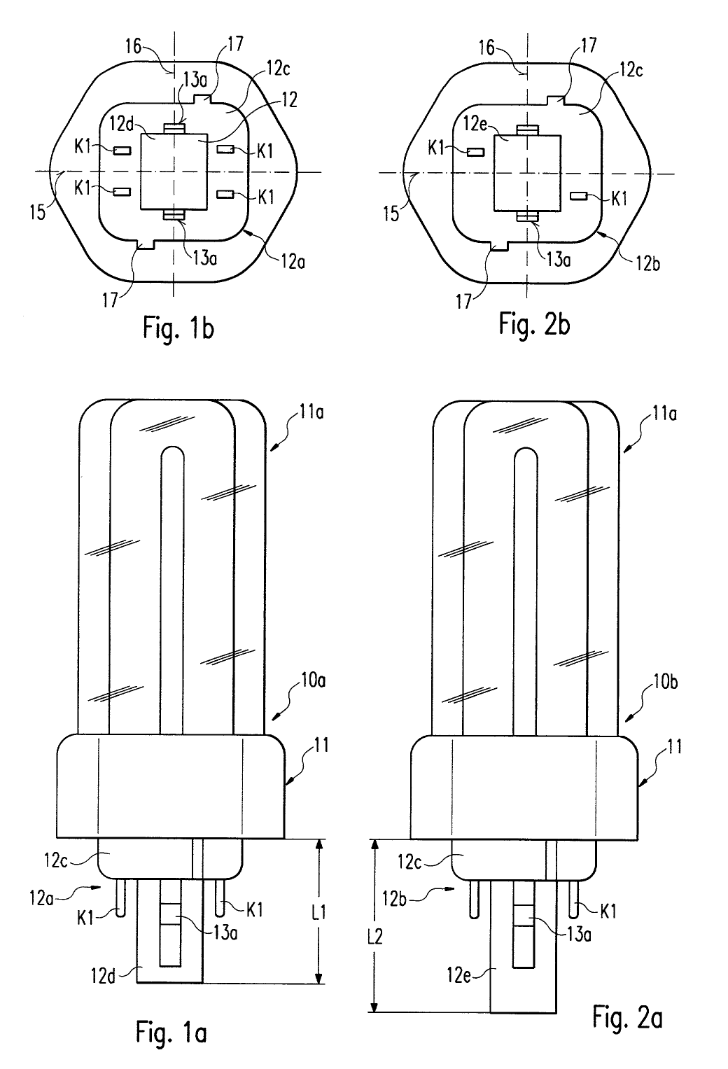

The compact fluorescent lamps 10a, 10b differ with regard to their external shaping in two respects. The compact fluorescent lamp 10a of the first lamp type has four contact pins K1 which stand up axis-parallel from the wide plug base section 12c, at a lateral spacing from the narrow plug base section 12d or 12e. With regard to the longitudinal middle planes 15, 16 of the base body 11, which run cross-rise (see FIG. 1b), the contact pins K1 are symmetrically arranged. On both sides of the longitudinal middle plane 16 there are arranged off centre, on the mutually opposing side surfaces of the wide plug base section 12c, molded webs 17, which extend axis-parallel and with regard to the respective longitudinal middle plane 15, 16 are arranged offset to both sides. The plug bases 12c, 12d, 12e may have, in cross-section, a rectangular or quadratic cross-sectional shape, if appropriate with rounded corners, as can be seen from FIGS. 1b and 2b.

A first difference of configuration between the two lamps consists in that the compact fluorescent lamp 10b of the second type has only two contact pins K1 which with regard to the longitudinal middle planes 15, 16 lie diametrically opposite to one another, but with regard to their position correspond to the positioning of the four contact pins K1 of the compact fluorescent lamp 10a, so that the positions of these two contact pins K1 coincide with the positions of the two corresponding contact pins K1 of the compact fluorescent lamp 10a.

The second difference of configuration between the compact fluorescent lamps 10a, 10b consists in that the length L1 of the plug base 12a is less than the length L2 of the plug base 12b of the second lamp type. The position of the latch cams 13a with regard to their similar spacings from the identically wide plug base sections 12c is, in contrast, the same for both lamp types.

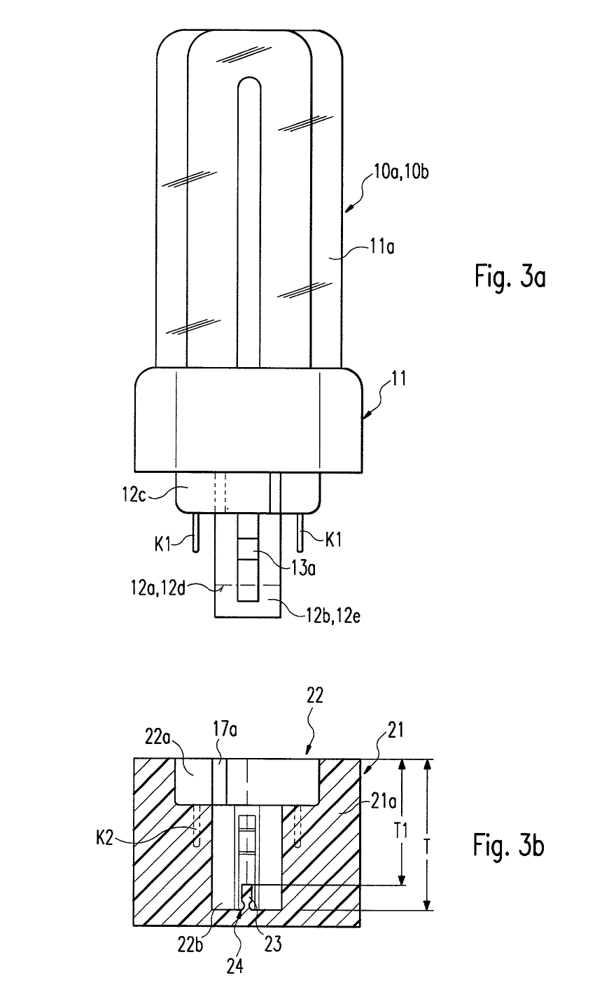

The holder 21, common for both lamp types, has in accordance with FIG. 3b a base recess 22 having a first wide base recess step 22a and a second narrow base recess step 22b, the depth T of the base recess 22 being the same as or somewhat greater than the length L2 of the plug base 12b. In the internal peripheral wall of the first base recess step 22a there are arranged axis-parallel grooves 17a the position and shape and size of which is adapted to the molded webs 17, with play for movement. In the region of the floor of the first base recess step 22a, there are contact elements K2, in particular contact sleeves, arranged in the holder body which are adapted to the position, shape and size of the contact pins K1.

In the floor region of the base recess 22 there is formed a stop element 23, formed on in one piece on the inner wall of the base recess 22, the spacing or depth T1 of which from the recess opening corresponds to the length L1 of the plug base 12a. Preferably the stop element 23 is formed on, on the floor surface of the base recess 22. It can be formed by means of a preferably centrally arranged pin or an elongate web. The web may extend in the transverse direction over the entire transverse dimension of the base recess 22 and be formed onto its side walls. In particular with this configuration the holder body, designated 21a, of the holder 21 is stabilized.

In the above-described configuration, the holder 21 is suitable to receive the plug base 12a of the compact fluorescent lamp 10a. For the plug base 12b of the compact fluorescent lamp 10b, the stop element 23 forms a blocking part, which prevents an insertion of the plug base 12b at least into the completely inserted position. By these means it is ensured that a compact fluorescent lamp 10b of the second lamp type cannot be plugged into the holder 21.

However, the holder 21 allows itself to be readily and rapidly so altered or adapted that it can also receive the plug base 12b of the compact fluorescent lamp 10b. For this purpose it is merely necessary to break off the stop element 23, which can be effected with the aid of a rod shaped tool, e.g. a screwdriver, inserted into the base recess 22, in a ready manner with little application of force.

The material of which at least the stop element 23 or the holder body 21 consists is of such a hardness or brittleness that the breaking off of the stop element 23 can be effected in a ready manner. Preferably, the stop element 23 has, in particular in the region of its connection to the holder body 21a, a preset break point 24 which on the one hand facilitates the breaking off and on the other hand makes it possible purposively at the desired point. The preset break point 24 may be formed e.g. by means of a tapering in shape of a groove, which is arranged on one or on both sides of the stop element 23 and is formed when the stop element 23 is formed on the holder body 21a. The holder body 21a is preferably of plastics or ceramics and is molded by means of injection molding or molding or pressure molding in one piece with the stop element 23 in a molding apparatus. The configuration in accordance with the invention also makes possible a simple and economical production or re-equipping of the molding apparatus, whereby the alteration of the mold chamber can be realized by means of a slider.

The above-described latching device 13 has, in the base recess 22, one laterally arranged latch nose 13b or two latch noses 13b arranged laterally opposite one another, which are mounted to be laterally elastically yielding, which upon plugging together elastically move away laterally into a free space and in the plugged-in position snap in behind the latch cams 13a. The elastic spring force of the latch noses 13b is so great that the latch noses 13b can be pressed over the latch cams 13a with a slight manual application of force. In order to make this possible, the latch cams 13a and/or the latch noses 13b have oblique or rounded lead-in surfaces and lead-out surfaces.

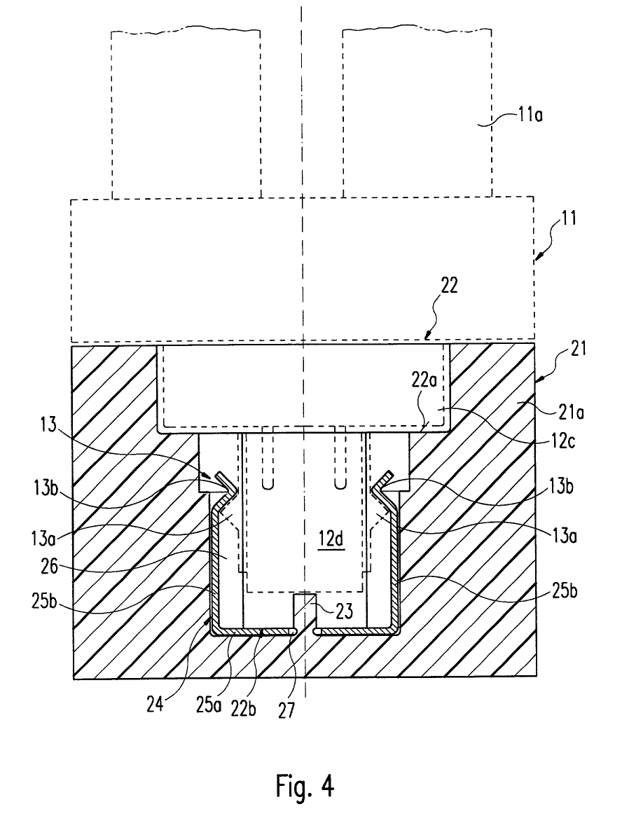

With the present exemplary embodiment the latch noses 13b are arranged in accordance with FIG. 4 at the free ends of a U-shaped spring 24, the spring web 25a of which bears on the recess floor, and the spring limbs 25b of which extend in each case in a gap 26 between the recess wall and the plug base section 12d or 12e in a direction towards the recess opening. The spring 24 is fixed in the recess floor in a non-illustrated manner. The web 25a of the spring 24 can be so shaped that it goes around the stop element 23 to the side, e.g. by means of a shaping out of the web 25a to the side. It is also possible, as can be seen in FIG. 4, to form a hole 27 in the web 25a so that for its installation the spring 24 can be pushed or press fit with the hole 27 onto the stop element 23 and the stop element 23 goes through the hole 27 with play for movement.

It is also possible to arrange a stop element 23 on one side of the spring web 25a or on each side of the web 25a.

When a web 25a is present the depth T of the base recess 22 is to be formed greater than described above, by the thickness of the web 25a.

1. A holder for compact fluorescent lamps which, in dependence upon whether they are operated with a magnetic or an electronic ballast, have either two contact pins and a longer plug base or four contact pins and a shorter plug base, said holder being formed with:
a plug recess the depth of which is at least equal to the length of the longer plug base;
four contact sleeves for receiving the two or the four contact pins; and
a stop element in the base recess to limit the insertion depth of the plug recess to that of the shorter plug base according to need,
said stop element being formed in one piece with the holder.

2. A holder according to claim 1, wherein
said holder has a molded base body, and wherein which can be produced by means of molding in a molding apparatus, in particular by means of injection molding, and in that the
said stop element is molded on the base body.

3. A holder according to claim 2, wherein
said holder body and the stop element are of plastics or porcelain.

4. A holder according to claim 2, wherein
said stop element is a pin or web provided in the base recess.

5. A holder according to claim 1, wherein
said stop element has a preset break point.

6. A holder according to claim 1, wherein
one lateral or two mutually opposing latch noses, for engaging behind a latch cam on the compact fluorescent lamps, is or are arranged in the base recess.

7. A holder according to claim 6, wherein
one latch nose is arranged on an angle-shaped spring or said latch noses are arranged on a U-shaped spring, having a spring web which is arranged in the floor of said base recess.

8. A holder according to claim 7, wherein
said spring web is formed with a hole through which said stop element extends.

9. A holder according to claim 7, wherein
said spring web is shaped outwardly laterally around said stop element.

10. A holder according to claim 7, wherein
said stop element is arranged laterally next to said spring web, or two stop elements are arranged on two sides of said spring web.

11. A holder according to claim 8, wherein
said stop element can be pushed through said hole with a press fit.
